(19) United States
(12) Patent Application Publication
(10) Pub. No.: US 2007/0126348 A1
(43) Pub. Date: Jun. 7, 2007

(54) Organic electroluminescent device

(75) Inventor: Chung-Yeh Iou, Wuci Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/365,174

(22) Filed: Mar. 1, 2006

(30) Foreign Application Priority Data
Dec. 1, 2005 (TW) 94142334

(51) Int. Cl. H01L 51/50

(52) U.S. Cl. 313/506; 428/690; 428/917; 313/504

(57) ABSTRACT

An organic electroluminescent device comprising a substrate is provided. An anode is disposed on the substrate. A first hole injection layer of fluorocarbon polymer is disposed on the anode. A second hole injection layer comprising a p-type dopant is disposed on the first hole injection layer. An electroluminescent layer is disposed on the second hole injection layer. A cathode is disposed on the electroluminescent layer.

### BACKGROUND OF THE INVENTION

### Field of the Invention

The invention relates to an organic electroluminescent device, and in particular to an organic electroluminescent device comprising fluorocarbon polymer and a hole injection layer with a p-type dopant.

Recently, electronic products consuming less electric power and occupying less space, such as mobile phones, personal digital assistant (PDA), and notebook computers, have seen increased demand. Among display devices, organic electroluminescent devices (OLED) have become popular due to their self-emitting, high luminesce, wider viewing angle, faster response speed, and simple fabrication process.

OLEDs are self-emitting devices containing organic materials. FIG. 1 is a cross-section of a conventional OLED comprising a substrate 11, with an anode 12, hole injection layer (HIL) 13, hole transport layer (HTL) 14, emissive layer (EML) 15, electron transport layer (ETL) 16 and cathode 17 respectively disposed thereon.

There are several types of OLEDs, but all utilize the same emissive principle. For example, Electrons and holes are propelled from the cathode 17 and anode 12 by applying a potential difference therebetween, injected into the EML 15 and recombined therein, resulting in luminescence of an OLED.

In order to inject holes and electrons from their respective electrodes 12 and 17 for recombination, carriers (electrons and holes) have to move across interfaces of heterojunctions. When carriers move across such interfaces, however, they have to cross energy barriers of the interfaces. For example, holes have to cross energy barriers of the interfaces between the anode 12 and HIL 13, HIL 13 and HTL 14, and HTL 14 and EML 15. Therefore, carriers' movements between these layers are less likely to occur as energy barriers become larger, resulting in carrier accumulation at interfaces, higher operating voltage and shorter lifetime.

In order to prevent the issues described above, thinner organic layers are usually formed between an anode 12 and EML 15 in a conventional OLED. However, problems of lower efficiency, lower stability and short circuits due to thinner organic layers all result.

Furthermore, dark pixels easily appear due to particles depositing on a panel during fabrication. Even in a clean room, some particles exist in surroundings, resulting in short circuit, lowered efficiency, short lifetime and lowered yield. Therefore, the particle issue is often a major problem causing failures of mass production and large panel.

Referring to FIG. 1, thickness of a HIL 13 and HTL 14 is about 80 to 170 nm in a conventional OLED 10, this can cover small particles but larger ones, and associated problems then appear. In order to prevent these problems, it is necessary to clean or renew fabricating apparatus, requiring manpower and material and financial resources. Results are not effective.

An OLED structure is disclosed in U.S. Pat. No. 6,849,345 comprising new material of a HTL to enhance luminous efficiency.

An OLED structure is disclosed in U.S. Pat. No. 6,841,267 comprising a new type dopant of an EML to enhance luminous efficiency and lifetime.

An OLED structure is disclosed in U.S. Pat. No. 6,818,329 comprising a metal layer disposed in a HTL to enhance luminous efficiency.

An OLED structure is disclosed in U.S. Pat. No. 6,692,846 comprising two HTLs to enhance luminous efficiency. One HTL comprises a stabilizing dopant and the other does not.

An OLED structure is disclosed in U.S. Pat. No. 6,208,077 comprising a polymer layer of fluorocarbon polymer disposed between a HTL and an anode to enhance operating stability.

However, particle issues described cannot be solved by the cited disclosures. Thus, an improved device for eliminating particle issues is called for.

### BRIEF SUMMARY OF THE INVENTION

A detailed description is given in the following embodiments with reference to the accompanying drawings.

In an embodiment, an organic electroluminescent device comprising a substrate is provided. An anode is disposed on the substrate. A first hole injection layer of fluorocarbon polymer is disposed on the anode. A second hole injection layer comprising a p-type dopant is disposed on the first hole injection layer. An electroluminescent layer is disposed on the second hole injection layer. A cathode is disposed on the electroluminescent layer.

### BRIEF DESCRIPTION OF THE DRAWINGS

The invention can be more fully understood by reading the subsequent detailed description and examples with references made to the accompanying drawings, wherein:

FIG. 1 is a cross section of a conventional OLED.

FIG. 2a is a cross section of an OLED in an embodiment of the invention.

FIG. 2b is a cross section of an OLED in another embodiment of the invention.

FIG. 3a shows a relationship between luminance and operating voltage.

FIG. 3b shows a relationship between luminous efficiency and luminance.

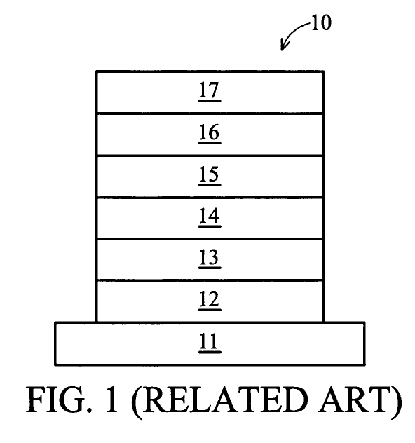

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

OLEDs of different HIL thickness can be formed depending on applications. In one aspect of the invention, a fluorocarbon polymer and a HIL comprising p-type dopant are both utilized, enhancing hole injection ability, preventing operating voltage from rising even when organic layer thickness between an EML and an anode is increased, thereby increasing lifetime.

In another aspect of the invention, the particle issues of an OLED during fabrication are eliminated by forming greater thickness of organic materials between an EML and anode, so that reliability of mass production for an OLED is increased, large OLED become possible, and an increase in operating voltage is prevented.

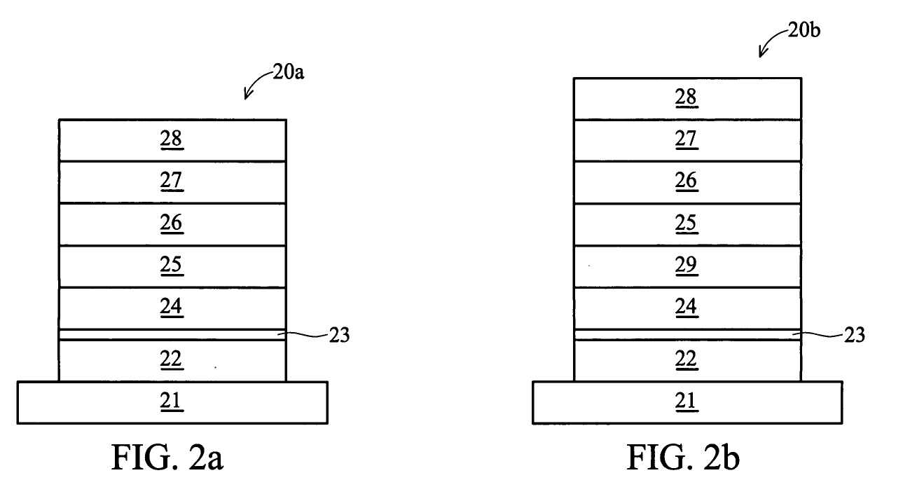

FIG. 2a is cross section of an OLED 20a in an embodiment of the invention, comprising a substrate 21, with anode 22, first HIL 23, second HIL 24, HTL 25, EML 26, ETL 27 and cathode 28 respectively disposed thereon. Electrons and holes are propelled from a cathode 28 and anode 22 by applying a potential difference therebetween, injected into an EML 26 and recombined therein, resulting in luminescence of an OLED.

The OLED 20a as shown in FIG. 2a is fabricated as follows.

A substrate 21 having an anode 22 is treated by ultraviolet ozone, decomposing organic matter deposited thereon.

A first HIL 23 of fluorocarbon polymer with a thickness of about 1 to 10 nm is deposited on the anode 22 by chemical vapor deposition (CVD) in an environment containing CHF₃ and O₂.

A second HIL 24, with a thickness of about several tens to several hundreds nm, comprising a p-type dopant with a concentration of about 1 to 25 vol %, is formed on the first HIL 23 by evaporation. Carrier mobility of the second HIL 24 is about 10⁻³ to 10⁻⁶ cm²V⁻¹s⁻¹. In an embodiment, the total thickness of the first HIL 23 and the second HIL 24 is about 150 to 1000 nm, and in another, about 300 to 1000 nm.

A HTL 25 with a thickness of about 10 to 100 nm is formed on the second HIL 24 by evaporation.

An EML 26 with a thickness of about 10 to 100 nm is formed on the HTL 25 by evaporation.

An ETL 27 with a thickness of about 10 to 100 nm is formed on the EML 26 by evaporation.

A cathode 28, comprising LiF with about l nm of thickness and aluminum with about 100 nm of thickness, is formed by evaporation. The LiF acts as an electron injection layer (EIL), while other EIL can also be formed between the cathode 28 and ETL 27.

FIG. 2b is cross section of an OLED 20b in another embodiment of the invention, comprising a substrate 21, with anode 22, first HIL 23, second HIL 24, third HIL 29, HTL 25, EML 26, ETL 27 and cathode 28 respectively disposed thereon. Electrons and holes are propelled from a cathode 28 and anode 22 by applying a potential difference therebetween, injected into an EML 26 and recombined therein, resulting in luminescence of an OLED.

The structure and fabrication of the OLED 20a is similar to the OLED 20b, a difference therebetween is that the OLED 20b further comprises a third HIL 29. It is noteworthy that the remaining components and fabrications of the two OLEDs 20a and 20b are identical, and like numerals denote like structures throughout FIGS. 2a and 2b.

As shown in FIG. 2b, substrate 21 is provided, and an anode 22, first HIL 23, and second HIL 24 are respectively formed thereon. Next, a third HIL 29, without p-type dopant, and with a thickness of several tens to several hundreds nm, is deposited on the second HIL 24 by evaporation. In an embodiment, the total thickness of the first HIL 23, second HIL 24 and third HIL 29 is about 150 to 1000 nm, and in another, about 300 to 1000 nm. After forming the third HIL 29, a HTL 25, EML 26, ETL 27 and cathode 28 are respectively formed thereon by evaporation, therefore completing the OLED 20b.

Materials used in the OLEDs 20a and 20b are as follows.

A substrate 21 can be of glass, plastic, ceramic, or semiconductor. Furthermore, the substrate 21 can be a transparent or opaque substrate. It can be a transparent substrate when an OLED is a dual-emissive OLED, and an opaque substrate when an OLED is a top-emissive OLED.

An anode 22 can be a transparent electrode or a metal electrode, comprising indium tin oxide (ITO), indium zinc oxide (IZO), aluminum zinc oxide (AZO), zinc oxide (ZnO), Li, Mg, Ca, Al, Ag, In, Au, Ni, or Pt, formed by a method such as sputtering, thermal evaporation, or plasma-enhanced chemical vapor deposition (PECVD).

A first HIL 23 can be of fluorocarbon polymer, abbreviated to CFₓH₍₄₋ₓ₎ or CFₓ.

A second HIL 24 is CuPc, m-MTDATA (4,4′,4″-Tris(N-3-methylphenyl-N-phenyl-amino)-triphenylamine), TPTE (N,N-Bis(4-diphenylaminobiphenyl)-N,N-diphenylbenzidine), NPB:F₄-TCNQ (N,N′-diphenyl-N,N′-bis(1-naphthyl)-(1,1′-bisphenyl)-4,4′-diamine:tetrafluoro-tetracyano-quinodimethane) or F₄-TCNQ:WO₃.

A p-type dopant doped in second HIL 24 is F₄-TCNQ, FeCl₃, V₂O₅, WO₃, MoO₃, Nb₂O₅ or Ir(OH)₃.

A third HIL 29 can be of the same material as the second HIL 24.

A HTL 25 can be allyl amine, diamine, or a derivative thereof. Diamine comprises NPB, T-PD (N,N′-diphenyl-N,N′-bis(3-methylphenyl)-(1,1′-bisphenyl)-4,4′-diamine), 1T-NATA (4,4′,4″-tris(N-(1-naphthyl)-N-phenyl-amino)-trisphenyl-amine), or 2T-NATA (4,4′,4″-tris(N-(2-naphthyl)-N-phenyl-amino)-trisphenyl-amine).

An EML 26 can be Alq₃:C545T (Tris(8-hydroxyquinoline)aluminum: 1H,5H,11H-[1]Benzopyrano[6,7,8,-ij]quinolizin-11-one,10-(2-benzothiazolyl)-2,3,6,7-tetrahydro-1,1,7,7,-tetramethyl-(9CI)), MADN:DSA-ph (2-methyl-9,10-di(2-naphthyl)anthracene: p-bis(p-N,N-di-phenyl-aminostyryl)benzene) or other suitable organic material.

An ETL 27 is Alq₃, metal quinolinate, oxadiazole, triazoles or phenanthroline.

Functional layers described above, such as a first HIL 23, second HIL 24, third HIL 29, HTL 25, EML 26 or ETL 27, can be of small molecule or polymer, and can be formed by thermal vacuum evaporation, spin coating, ink jet, screen printing, dip coating, roll-coating, injection-fill, embossing, stamping, physical vapor deposition, or chemical vapor deposition. An EML 26 comprises a light-emitting material and a dopant doped therein. Amount of dopant depends on applications.

A cathode 28 can be of aluminum, aluminum lithium alloy or magnesium silver alloy.

The highest occupied molecular orbit (HOMO) of the second HIL 24 as shown in FIG. 2a is increased, and energy barrier between the second HIL 24 and HTL 25 is lowered by an additive p-type dopant doped in the second HIL 24. Energy barrier between the anode 22 and second HIL 24 is lowered by utilizing the first HIL 23 of fluorocarbon polymer, so that holes can easily reach the EML 26 from the anode 22 through the first HIL 23, second HIL 24 and HTL 25, thereby enhancing hole injection efficiency, increasing lifetime, and preventing an increase in operating voltage.

Particle issues can be eliminated by thickening the first HIL 23, second HIL 24 and HTL 25, with no increase in operating voltage.

The invention will be better understood by reference to the following illustrative and non-limiting representative embodiments, selected from FIG. 2b, showing the preparation of the OLED 20b, and comparing experimental results with a comparative OLED.

A comparative OLED was fabricated as follows.

A substrate with an anode having a thickness of 75 nm was treated by ultraviolet ozone to decompose organic matter thereon. A HIL of phenyl amine with a thickness of 150 nm, comprising p-type dopant of F₄-TCNQ with 2 vol %, was formed on the anode by evaporation. A HTL of NPB with a thickness of 20 nm was formed on the HIL by evaporation. An EML of Alq₃:C545T with a thickness of 30 nm was formed on the HTL by evaporation. An ETL of Alq₃ with a thickness of 30 nm was formed on the EML by evaporation. A cathode, comprising LiF with 1 nm of thickness and aluminum with 100 nm of thickness, was formed on the ETL by evaporation.

An OLED of embodiment 1 was fabricated by following steps.

A substrate with an anode of indium tin oxide (ITO) having a thickness of 75 nm was treated by ultraviolet ozone to decompose organic matter thereon. A first HIL of fluorocarbon polymer with a thickness of about 1 nm was deposited on the anode by chemical vapor deposition in an environment containing CHF₃ and O₂. A second HIL of phenyl amine with a thickness of about 60 nm, comprising p-type dopant of F₄-TCNQ with 2 vol %, was formed on the first HIL by evaporation. A third HIL, of phenyl amine with a thickness of about 90 nm, without p-type dopant, was formed on the second HIL by evaporation. A HTL of NPB with a thickness of about 20 nm was formed on the third HIL by evaporation. An EML of Alq₃:C545T with a thickness of about 30 nm was formed on the HTL by evaporation. An ETL of Alq₃ with a thickness of about 30 nm was formed on the EML by evaporation. A cathode, comprising LiF with about 1 nm of thickness and aluminum with about 100 nm of thickness, was formed on the ETL by evaporation.

OLEDs of embodiments 2 and 3 were fabricated as embodiment 1, differing in second HIL thickness, which is about 150 nm in embodiment 2, and about 200 nm in embodiment 3.

The thickness of the first, second and third HIL are respectively about 1 nm, 200 nm and 90 nm in embodiment 3, so that the total thickness of these layers is about 300 nm. In other embodiments, HILs having total thickness exceeding 300 nm can also be formed. In yet another embodiment, the three HILs, each having different thickness from embodiment 3, accumulating 300 nm of total thickness can also be formed.

It is noteworthy that the embodiments 1, 2 and 3 based on FIG. 2b are presented for illustration, while another embodiment based on FIG. 2a provides similar properties as embodiment based on FIG. 2b, since the OLED based on FIG. 2a, like the OLED based on FIG. 2b, comprises fluorocarbon polymer and a HIL having p-type dopant.

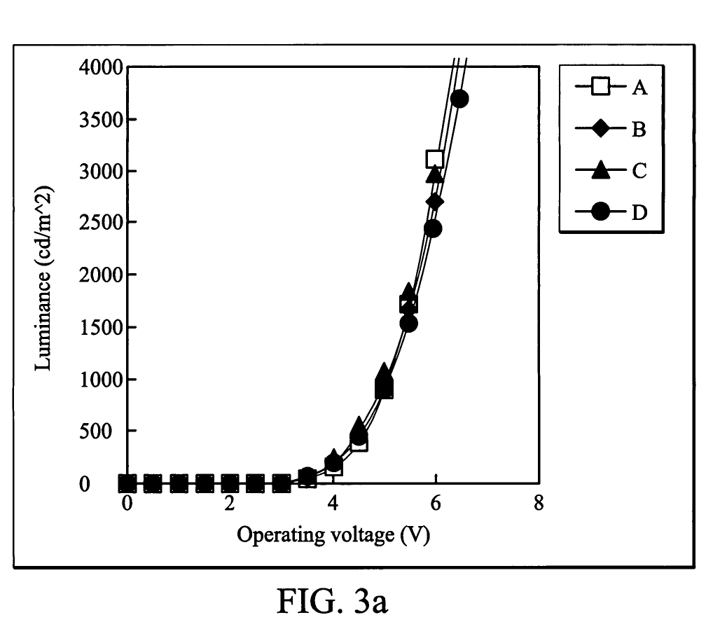

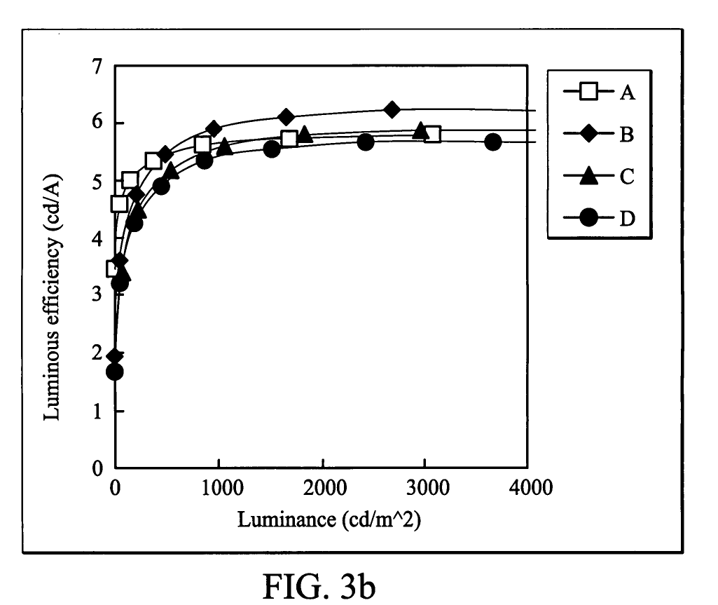

The experimental results of the comparison and the embodiments 1, 2 and 3 are shown in FIGS. 3a and 3b. FIG. 3a shows a relationship between luminance and operating voltage. FIG. 3b shows a relationship between luminous efficiency and luminance. Curves A, B, C and D respectively indicate the experimental results of comparison, embodiment 1, 2 and 3.

As shown in FIG. 3a, luminance values of curves A, B, C and D are almost the same. Referring to FIG. 3b, luminous efficiency values of curves A, B, C and D are also similar.

As shown in FIGS. 3a and 3b, operating voltage and luminous efficiency of curves A and D are respectively 6V and 5.8 cd/A while reaching 3000 ch/m² of luminance, indicating the OLED, with a total thickness of about 300 nm of the three HILs according to embodiment 3, have properties similar to the comparative OLED with thinner HIL of 150 nm. Operating voltage is not increased and the luminous efficiency is not decreased, even though the total thickness of HILs in embodiment 3 exceeds that in the comparison.

Particle issues of an OLED during fabrication can be eliminated by forming thicker organic materials between an EML and anode, so that the reliability of an OLED for mass production is increased, large OLED becomes possible, and an increase in operating voltage is prevented.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic electroluminescent device, comprising:
a substrate;
an anode disposed on the substrate;
a first hole injection layer (HIL) of fluorocarbon polymer disposed on the anode;
a second HIL comprising a p-type dopant disposed on the first HIL;
an electroluminescent layer disposed on the second HIL; and
a cathode disposed on the electroluminescent layer.

2. The device of claim 1, wherein the electroluminescent layer comprises a hole transport layer (HTL) disposed on the second HIL, an emissive layer (EML) disposed on the HTL and an electron transport layer (ETL) disposed on the EML.

3. The device of claim 1, further comprising an electron injection layer (EIL) disposed between the electroluminescent layer and the cathode.

4. The device of claim 1, wherein the second HIL has a mobility of 10⁻³ to 10⁻⁶ cm²V⁻¹s⁻¹.

5. The device of claim 1, wherein the first HIL and the second HIL have a total thickness of 150 to 1000 nm.

6. The device of claim 1, wherein the first HIL and the second HIL have a total thickness of 300 to 1000 nm.

7. The device of claim 1, wherein the first HIL has a thickness of 1 to 10 nm.

8. The device of claim 1, wherein the second HIL is CuPc, m-MTDATA, TPTE, NPB:F₄-TCNQ or F₄-TCNQ:WO₃.

9. The device of claim 1, wherein the p-type dopant is F₄-TCNQ, FeCl₃, V₂O₅, WO₃, MoO₃, Nb₂O₅ or Ir(OH)₃.

10. The device of claim 1, wherein the first HIL is disposed adjacent to the second HIL.

11. The device of claim 1, wherein the second HIL has a concentration of 1 to 25 vol % of the p-type dopant.

12. The device of claim 1, further comprising a third HIL disposed between the electroluminescent layer and the second HIL, wherein the third HIL does not comprise the p-type dopant.

13. The device of claim 12, wherein the first, second and third HIL have a total thickness of 150 to 1000 nm.

14. The device of claim 12, wherein the first, second and third HIL have a total thickness of 300 to 1000 nm.

15. The device of claim 12, wherein the third HIL is CuPc, m-MTDATA, TPTE, NPB:F₄-TCNQ or F₄-TCNQ:WO₃.
